(19) United States
(12) Patent Application Publication
(10) Pub. No.: US 2016/0105191 A1
(43) Pub. Date: Apr. 14, 2016

(54) FREQUENCY SYNTHESIZER

(71) Applicant: ZAKRYTOE AKCIONERNO OBSHHESTVO "NAYCHNO- PROIZVODSTVENNAYA FIRMA "MICRAN", Tomsk (RU)

(72) Inventor: Andrei Viktorovich GOREVOI, Tomsk (RU)

(73) Assignee: ZAKRYTOE AKCIONERNO OBSHHESTVO "NAYCHNO- PROIZVODSTVENNAYA FIRMA "MICRAN", Tomsk (RU)

(21) Appl. No.: 14/782,921

(22) PCT Filed: Apr. 3, 2014
(86) PCT No.: PCT/RU2014/000245

§ 371 Date: Dec. 30, 2015

(30) Foreign Application Priority Data
Apr. 9, 2013 (RU) 2013115792

(51) Int. Cl. H03L 7/18

(52) U.S. Cl. CPC H03L 7/18

(57) ABSTRACT

The output of a reference frequency generator is connected to the input of a high-order frequency multiplier, the output of which is connected to the input of an additional frequency multiplier and to a first input of a frequency converter. The output of the additional frequency multiplier is connected to the input of a frequency divider, the output of which is connected to a reference input of a frequency-phase detector. The output of the frequency converter is connected to the input of a frequency divider with a variable division ratio, the output of which is connected to another input of the frequency-phase detector. The output of the frequency-phase detector is connected to an error signal filter, the output of which is connected to the input of a controlled generator. A second input of the frequency converter is connected to the output of the controlled generator. The main technical result is an increase in the frequency resolution and spectral purity of an output signal.

### CROSS-REFERENCE TO RELATED APPLICATION

This application is a national stage patent application of international application no. PCT/RU2014/000245 filed on Apr. 3, 2014. The earliest priority date claimed is Apr. 9, 2013.

### FEDERALLY SPONSORED RESEARCH

Not Applicable

### SEQUENCE LISTING OR PROGRAM

Not Applicable

### BACKGROUND

This invention is related to the instrumentation, radiolocation and telecommunication fields.

There is a frequency synthesizer with digital phase lock loop (PLL) (Chenakin A., Frequency Synthesizers: Concept to Product, 2011, 152 pages), which includes the frequency phase detector, frequency divider with fractional variable coefficient of division N times, control signal filter and controlled generator.

The deficiencies of this product is a high noise level, due to PFD, and a low-frequency resolution due to low K values up to 25, which are produced in microchips and output 3-6 Hz resolution at minimal level of phase noise.

There is a single-loop synthesizer with a frequency conversion feedback (Chenakin A. A compact, agile, low-phase-noise frequency source with AM, FM and pulse modulation capabilities, 2009, 2 pages), which improves the spectral frequency of the output signal and improves the frequency resolution by replacing the frequency divider with a frequency converter and integrating a frequency multiplier and digital computing synthesizer, which currently has the best frequency resolution. The deficiencies of this device is a significant energy consumption and its dimensions.

### The Nature of Invention

The main technical result of the proposed solution is an increase in frequency resolution and spectral frequency of the output signal, while avoiding a significant increase in energy consumption and device dimensions.

The main technical result is achieved by a frequency synthesizer, which includes a frequency oscillator, whose output is connected with a frequency multiplier; frequency converter, frequency divider, whose output is connected with a frequency phase detector input, whose output is connected with error signal filter input, whose output is connected to the controlled generator input. Per the proposed solution, the frequency multiplier output is connected with an additional frequency multiplier input, whose output is connected to the frequency divider input, whose output is connected to the frequency phase detector input, while the frequencies of the controlled generator and frequency oscillator are correlated by the following formula:

F_{yr}=NKRFₒᵣ(1±1/M);
where: N—variable division coefficient of the frequency divider;
F_{yr}—controlled generator frequency;
M—multiplying coefficient of the frequency multiplier;
Fₒᵣ—frequency of the frequency oscillator;
K—multiplying coefficient of the additional frequency multiplier;
R—division coefficient of the frequency divider.

Reasonably, frequency dividers and frequency phase detector shall be in a single integrated circuit.

### DRAWINGS

FIG. 1 shows the block diagram of the frequency synthesizer.

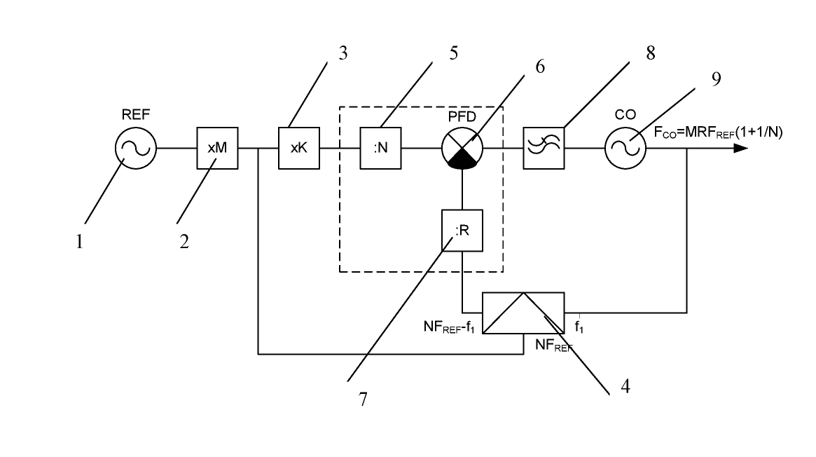

### DETAILED DESCRIPTION

The synthesizer consists of a reference frequency generator 1, whose output is connected to the input of a high-order frequency multiplier 2, whose output is connected to the input of an additional frequency multiplier 3 and to a first input of a frequency converter 4. The output of the additional frequency multiplier 3 is connected to the input of a frequency divider 5 with fractional variable division ratio, whose output is connected to a reference input of a frequency phase detector 6. The output of the frequency converter 4 is connected to the input of a frequency divider 7 with a variable division ratio, whose output is connected to another input of the frequency phase detector 6. The output of the frequency phase detector 6 is connected to an error signal filter 8, whose output is connected to the input of the controlled generator 9. The second input of the frequency converter 4 is connected the output of the controlled generator 9. Frequency dividers 5, 7, and the frequency phase detector 6 are in the single integrated circuit.

Invention Implementation

The output signal of the frequency multiplier 2 is separated by power and fed to the input of the additional frequency multiplier 3 and to the input of the frequency converter 4. The output signal of the additional frequency multiplier 3 is connected to the input of the frequency divider 5 with a fractional variable division ratio, defined by the following formula:

N=INT+(FRAC/MOD)

where:
N—is the division ratio value of the frequency divider;
INT—is the programmable whole number of the division ratio N;
FRAC and MOD—are programmable numbers, which define the fractional part of the division ratio N.

The output signal of the frequency divider 5 is fed to the reference input of the frequency phase detector 6. The signal from the controlled generator 9 is sent to the second input of the frequency converter 4. The differential frequency signal is taken from the frequency converter output 4 and sent to the input of the frequency divider 7 with a variable division ratio, whose output signal is connected to the second input of the frequency phase detector 6. The frequency phase detector 6 generates an error signal, proportional to the phase desynchronization between its input signals. After being filtered by a filter of error signal 8, this signal is sent to the frequency control input of the controlled generator 9. The frequencies of the controlled generator 9 and the reference generator 1 are related by the following ratio:

F_{yr}=NKRFₒᵣ(1±1/M);

while the frequency resolution equals to: ΔF_{yr}=NKRFₒᵣ/MODM

During the operational mode of the frequency phase detector 6, MK/N≦1, R<<N, which improves the frequency resolution by N/R times, when compared to the synthesizer with frequency divider with fractional variable division ratio feedback.

What is claimed:

1. A frequency synthesizer, including the reference generator, whose output is connected to the frequency multiplier, the frequency converter, frequency divider, whose output is connected to the input of the frequency phase detector, whose output is connected to the input of the error signal filter, whose output is connected to the input of the controlled generator, distinguished by the fact that the input of the frequency multiplier is connected to the input of the additional frequency multiplier, whose output is connected to the input of the frequency divider, whose output is connected to the reference input of the frequency phase detector, while the frequencies of the controlled generator and the reference generator are related by the following formula
F_{yr}=NKRFₒᵣ(1±1/M);
where: N—variable division coefficient of the frequency divider;
F_{yr}—controlled generator frequency;
M—multiplying coefficient of the frequency multiplier;
Fₒᵣ—frequency of the frequency oscillator;
K—multiplying coefficient of the additional frequency multiplier;
R—division coefficient of the frequency divider.

2. The frequency synthesizer in claim 1, but with frequency dividers and frequency phase detector in a single integrated circuit.
